(19) United States
(12) Patent Application Publication
(10) Pub. No.: US 2005/0178661 A1
(43) Pub. Date: Aug. 18, 2005

(54) Physical vapor deposition targets

(76) Inventors: Wuwen Yi, Veradale, WA (US); Chi tse Wu, Veradale, WA (US); Diana Morales, Veradale, WA (US)

Correspondence Address: WELLS ST. JOHN P.S., 601 W. FIRST AVENUE, SUITE 1300, SPOKANE, WA, 99201, US

(21) Appl. No.: 11/108,302

(22) Filed: Apr. 18, 2005

Related U.S. Application Data
(62) Division of application No. 10/405,850, filed on Apr. 1, 2003.
(60) Provisional application No. 60/395,072, filed on Jul. 10, 2002.

(51) Int. Cl. C23C 14/32

(52) U.S. Cl. 204/298.12; 204/298.13; 419/26

(57) ABSTRACT

The invention includes methods of forming physical vapor deposition targets, and includes targets and target assemblies. The methods of forming the targets comprise hot-pressing or die forging of suitable materials to form a target blank. The target blank has a pair of opposing surfaces, with one of the opposing surfaces having a topography that is substantially an inverse of an expected wear profile. The target blank can be bonded to a backing plate to form a target assembly or can be utilized as a monolithic target.

### RELATED PATENT DATA

This patent claims benefit of priority under 35 U.S.C. §119 to U.S. Provisional Patent Ser. No. 60/395,072, which was filed Jul. 10, 2002.

### TECHNICAL FIELD

The invention pertains to methods of forming physical vapor deposition (PVD) targets (such as, for example, sputtering targets), and further encompasses the targets formed by the methods.

### BACKGROUND OF THE INVENTION

A sputtering method is described with reference to FIG. 1, which illustrates a PVD target 10 spaced from a substrate 12 by a distance T/S. Distance T/S is referred to as the target substrate distance. Substrate 12 can comprise, for example, a semiconductive material wafer. Target 10 can comprise numerous materials known to persons of ordinary skill in the art, such as, for example, metallic materials (e.g. one or more of aluminum, copper, titanium, tantalum, tungsten, cobalt, nickel, tungsten, ruthenium, gold, molybdenum, etc.), or ceramic materials (e.g., BaTiO₃, Pb(Zr, Ti)O₃, BiSrTaO₃, etc.). Also, target 10 can comprise numerous shapes. For instance, FIG. 2 illustrates that target 10 can comprise a circular shape.

Referring again to FIG. 1, a shield 14 is provided over a peripheral region of target 10. Shield 14 can comprise, for example, stainless steel or aluminum.

In operation, material from target 10 is sputter-deposited onto substrate 12. More specifically, target 10 has a face surface 16 which is exposed to high energy ions and/or atoms. The high energy ions and/or atoms eject atoms from surface 16, and the ejected atoms are subsequently deposited onto substrate 12. Shield 14 protects peripheral edges of target 16 from being exposed to the high energy ions and/or atoms. One of the goals in target fabrication is to deposit a uniform film of material over substrate 12. One aspect of achieving a uniform film is to have an appropriate T/S distance between target surface 16 and substrate 12, as well as to maintain a substantially common T/S distance from the entirety of the sputtered target face 16 and substrate 12. Shield 14 is provided to alleviate problems which could occur if the sloped regions of target 10 were exposed to high energy ions and/or atoms during a sputtering process.

FIG. 3 illustrates target 10 after the target has been subjected to the wear of having material sputtered therefrom. Specifically, FIG. 3 illustrates a wear profile formed across sputtered face surface 16. The illustrated wear profile is for exemplary purposes only. The shape of an actual wear profile can depend on, for example, the magnet type and target life of materials used in a sputtering process. A dashed line 18 is provided in FIG. 3 to illustrate the starting position of the face surface when target 10 was new (i.e., the face surface shown in FIG. 1). As shown in FIG. 3, a number of troughs (i.e., sputter tracks) are formed within face surface 16 during the sputtering operation. Accordingly, the target does not wear uniformly across the surface 16.

Attempts have been made to improve target lifetime by adding additional material to a target to compensate for the uneven wear pattern of FIG. 3. For instance, FIG. 4 illustrates a target 20 which attempts to compensate for the uneven wear of FIG. 3. Target 20 is shown with a dashed line 18 illustrating the position of original face 16 in the target 10 of FIGS. 1-3. FIG. 4 also shows additional material 22 provided over original position 18, and in locations which compensate for the uneven wear profile of FIG. 3. Accordingly, target 20 has a face surface 24 which effectively comprises a mirror image of the wear profile of FIG. 3.

The FIG. 4 target is typically formed by carving or otherwise machining the desired topography of the target from a blank. The machining can be time-consuming and expensive due to the large amount of material removed. Also, some materials are difficult to machine due to brittleness or other physical properties of the materials. Additionally, there are cases in which material removed during the machining cannot be economically recycled, which results in waste of the material.

It would be desirable to develop new techniques for forming PVD targets.

### SUMMARY OF THE INVENTION

In one aspect, the invention encompasses a method of forming a physical vapor deposition target. One or more powders are hot-pressed to form a target blank. The target blank has a pair of opposing surfaces, with one of the opposing surfaces being substantially flat and the other having a topography that is substantially an inverse of an expected wear profile. The target blank is bonded to a backing plate to form a target assembly. The surface having a topography which is a substantial inverse of the expected wear profile extends outward from the target,assembly as a sputtering surface of the assembly.

In one aspect, the invention encompasses a method of forming a sputtering target by die-forging malleable material to form a target blank. The target blank has a pair of opposing surfaces, with one of the opposing surfaces being substantially flat and the other having a topography that is substantially an inverse of an expected wear profile.

In one aspect, the invention encompasses a sputtering target consisting essentially of tungsten, and in another aspect the invention encompasses a sputtering target consisting essentially of tungsten and titanium.

### BRIEF DESCRIPTION OF THE DRAWINGS

Preferred embodiments of the invention are described below with reference to the following accompanying drawings.

FIG. 1 is a diagrammatic, cross-sectional view illustrating a prior art sputtering target and substrate.

FIG. 2 is a view along the line 2-2 of FIG. 1.

FIG. 3 is a diagrammatic, cross-sectional view of a prior art sputtering target after the target has been subjected to the wear of a sputtering operation.

FIG. 4 is a diagrammatic, cross-sectional view of a prior art sputtering target illustrating prior art methodology for increasing the lifetime of a sputtering target.

FIG. 5 is a diagrammatic, cross-sectional view of an apparatus utilized in an exemplary aspect of the present invention, and shown at an initial processing stage of such aspect.

FIG. 6 is a view of the FIG. 5 apparatus shown at a processing stage subsequent to that of FIG. 5.

FIG. 7 is a view of a physical vapor deposition target blank formed utilizing the processing of FIG. 5 and 6.

FIG. 8 is a view of the target blank of FIG. 7 bonded to a backing plate to form a physical vapor deposition target assembly.

FIG. 9 is a diagrammatic, cross-sectional view of an apparatus which can be utilized in a second aspect of the invention. The apparatus of FIG. 9 is shown at an initial processing stage of the second aspect of the invention.

FIG. 10 is a view of the FIG. 9 apparatus shown at a processing stage subsequent to that of FIG. 9.

FIG. 11 is a view of a physical vapor deposition target assembly comprising a target formed from the processing of FIGS. 9 and 10 bonded to a backing plate.

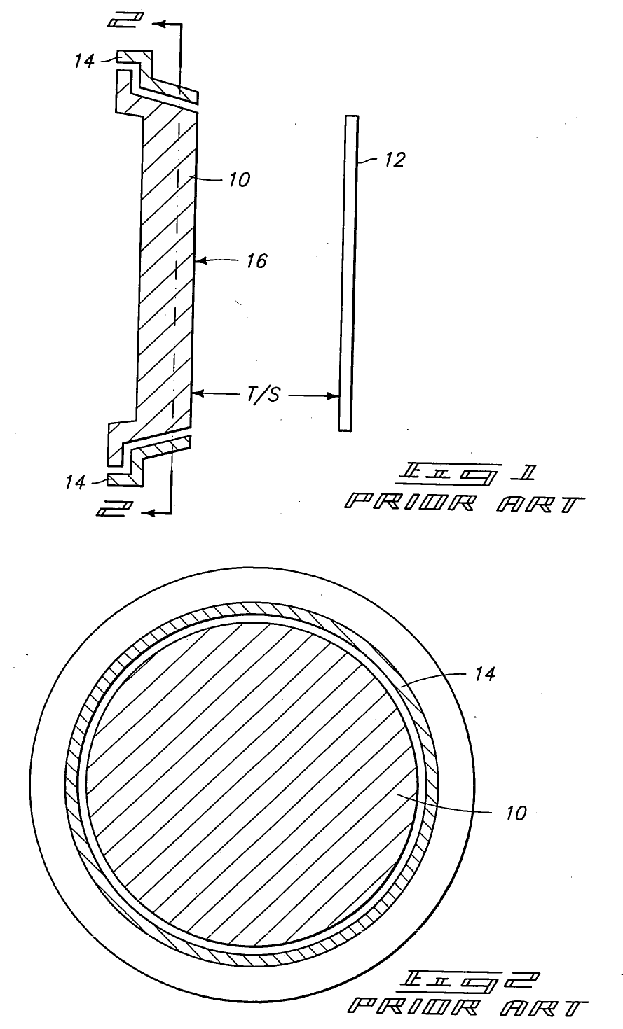

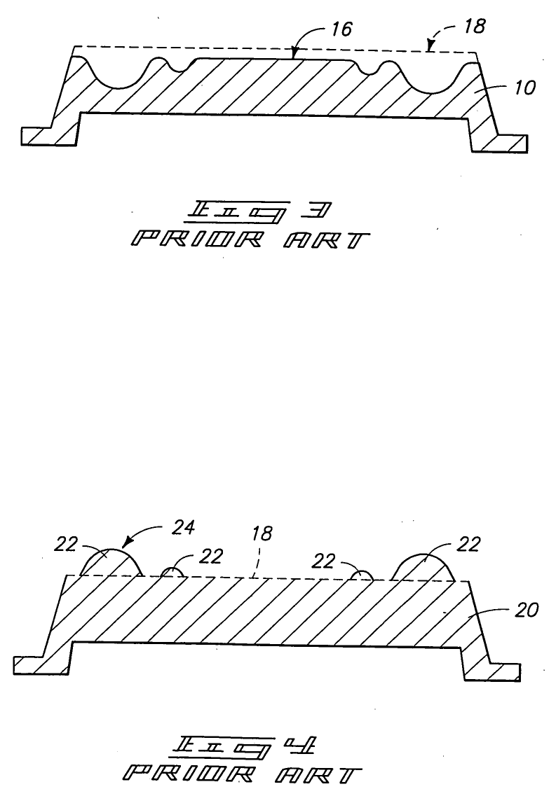

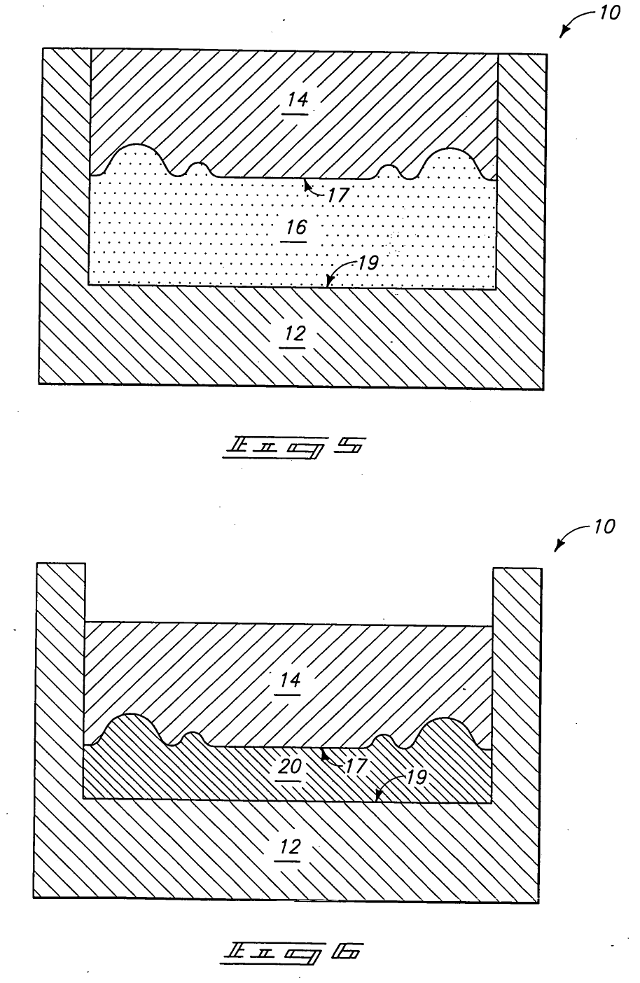

### DETAILED DESCRIPTION OF THE PREFERRED EMBODIMENTS

One aspect of the invention is described with reference to FIGS. 5-8. referring initially to FIG. 5, an apparatus 10 comprises a first mold portion 12 and a second mold portion 14 moveably engaged relative to the first mold portion. Mold portions 12 and 14 can comprise, for example, graphite.

One or more powders 16 are provided between mold portions 12 and 14. The powder 16 can comprise, consist essentially, or consist of, for example, one or more of tantalum, tungsten and titanium.

Mold 14 comprises a surface 17 proximate powder 16, and mold portion 12 comprises a surface 19 proximate the powder. Surface 17 has a topography that is approximately the same as an expected wear profile of a target produced from apparatus 10 (FIG. 3 shows an exemplary wear profile). In particular aspects, surface 17 can have a topography that corresponds exactly to an expected wear profile of a target produced from apparatus 10.

Surface 19 of mold portion 12 is substantially flat.

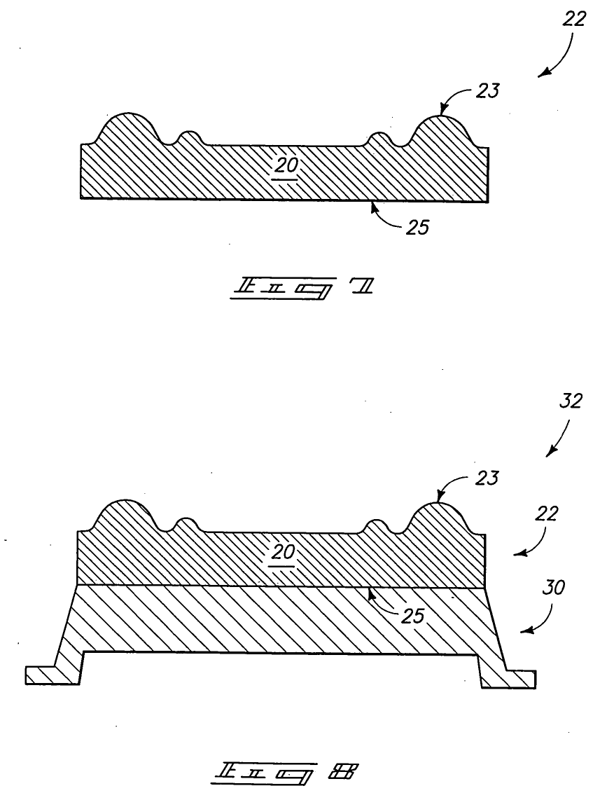

Referring to FIG. 6, mold portions 12 and 14 are moved relative to one another to compress powder 16 (FIG. 5) between them, and form a solid material 20 from the powder. Such pressing of powder 16 between portions 12 and 14 can correspond to, for example, vacuum hot pressing.

The movement of portions 12 and 14 relative to one another can comprise movement of one or both of mold portions 12 and 14. In the shown embodiment, mold portion 14 is moved relative to mold portion 12, and is slideably engaged within an interior portion of mold of mold portion 12. It is to be understood that the invention encompasses other embodiments, such as, for example, embodiments in which mold portion 12 is moved relative to portion 14, and is slideably engaged within a region of portion 14. Further, although portion 14 is shown as a top portion in the illustrated embodiment, it is to be understood that the apparatus can be utilized in a number of different orientations, including orientations in which mold portion 14 is a bottom portion.

Referring to FIG. 7, material 20 is removed from apparatus 10 (FIG. 6). Material 20 has a shape corresponding approximately to a desired physical vapor deposition target, and in particular embodiments has a shape corresponding exactly to a desired physical vapor deposition target. Material 20 can be considered to be in the shape of a target blank 22. Target blank 22 has a pair of opposing surfaces 23 and 25. Surface 25 is substantially flat, whereas surface 23 has a topography that is substantially an inverse of an expected wear profile.

Target blank 22 can be considered to be in a near net shape of a desired target. To the extent that the topography of surface 23 is not within desired tolerances of a final shape of a target formed from target blank 22, machining can be utilized to refine the topography of surface 23. The machining can be utilized not only to adjust dimensions of the topography of surface 23, but also to impart a desired surface finish to surface 23.

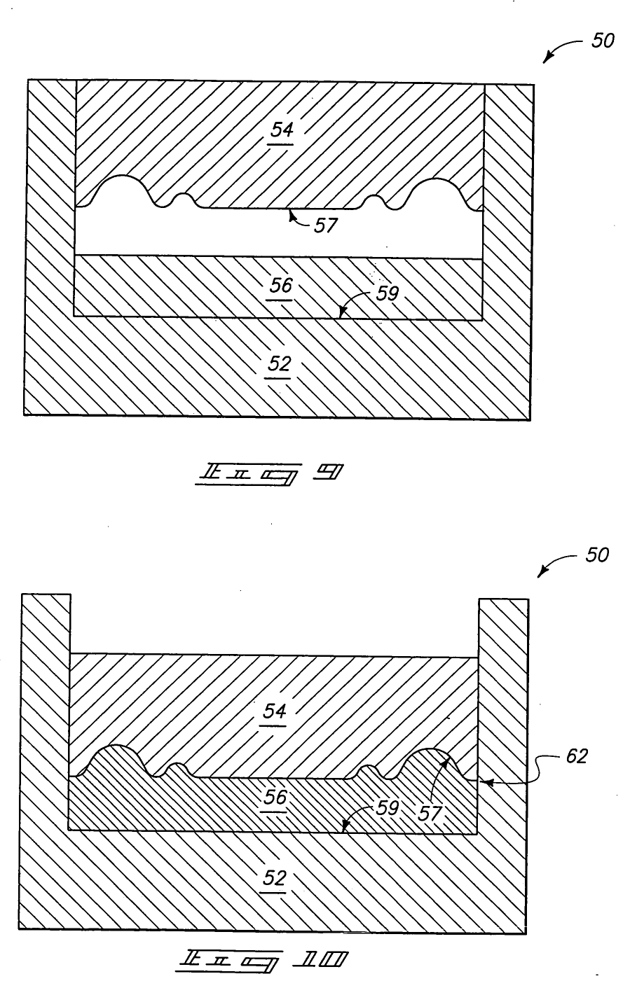

Referring to FIG. 8, target blank 22 is bonded to a backing plate 30. Such bonding can be accomplished utilizing conventional methods, including, for example, solder bonding and/or diffusion bonding. The backing plate 30 and target blank 22 together form a target assembly 32. Surface 23 extends outwardly from the target assembly, and ultimately functions as a sputtering surface of the target in a physical vapor deposition operation utilizing the target assembly 32. To the extent that surface 23 is machined, such machining can occur before or after bonding target blank 22 to backing plate 30. Although the target blank is shown bonded to a backing plate, it is to be understood that the target blank could, in other aspects of the invention, be formed to have a configuration suitable for utilization without bonding to a backing plate (i.e., could be a monolithic target). In such applications, the target can be, for example, formed in a shape comparable to that of the assembly 32.

Another aspect of the invention is described with reference to FIGS. 9-11.

Referring initially to FIG. 9, an apparatus 50 comprises a first mold portion 52 and a second mold portion 54. A malleable material 56 is placed between mold portions 52 and 54. Malleable material 56 can, for example, comprise, consist essentially, or consist of one or more of copper, tantalum, molybdenum, titanium, aluminum, nickel, cobalt and gold. Mold portion 54 comprises a surface 57 proximate material 56, and mold portion 52 comprises a surface 59 proximate material 56. Surface 54 comprises a topography corresponding approximately to an expected wear profile of a target produced from apparatus 50, and surface 59 is substantially flat.

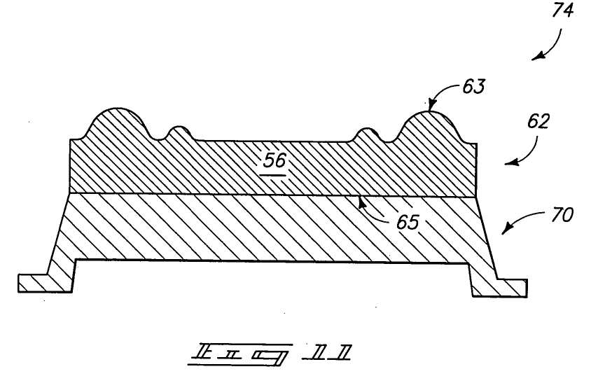

Referring to FIG. 10, mold portions 52 and 54 are moved relative to one another to compress malleable material 56 between the portions 52 and 54. The movement of portions 52 and 54 relative to one another can comprise movement of one or both of portions 52 and 54. In the shown embodiment, portion 54 is moved relative to portion 52. The compression of malleable material 56 forms material into a target blank 62. The compression of material 56 can be referred to as a die-forging operation.

The mold portions 52 and 54 of FIG. 9 can be formed of appropriate metal. The pressure and temperature utilized during compression of material 56 can be determined by persons of ordinary skill in the art, and will be those suitable for forcing malleable material 56 into the cavities associated with surface 57 of mold portion 54.

Referring to FIG. 11, target blank 62 is shown removed from apparatus 50 (FIG. 10), and bonded to a backing plate 70. Target blank 62 can be bonded to backing plate 70 utilizing conventional methodologies, including, for example, solder bonding or diffusion bonding. Target blank 62 and backing plate 70 together form a target assembly 74. Target blank 62 comprises a surface 63 having a topography that is substantially inverse of an expected wear profile. Such surface extends outwardly from target assembly 74 to function as a sputtering surface of assembly 74 during utilization of assembly 74 in physical vapor deposition processes.

To the extent that surface 63 does not correspond to a desired topography within appropriate tolerances as formed from apparatus 50 (FIG. 10), the surface can be machined to refine the topography to more closely approximate the inverse of the expected wear profile of the target. Such machining can occur before and/or after bonding of target blank 62 with backing plate 70.

Target blank 62 comprises a flat surface 65 which is utilized in bonding target blank 62 to backing plate 70.

Although the target blank is shown bonded to a backing plate, it is to be understood that the target blank could, in other aspects of the invention, be formed to have a configuration suitable for utilization without bonding to a backing plate (i.e., could be a monolithic target).

Utilization of the methodology of the present invention can improve the economy of forming a target blank relative to prior art methodologies. Specifically, since a target blank is formed to have a topography which is approximately the inverse of a wear profile, a significant amount of target material can be saved relative to targets which do not have such topography. Further, since the topography is formed by pressing methods which create a target having a near net shape, or in particular embodiments having an exact net shape, there is little to no machining of the target blanks utilized to form the desired topography. The utilization of little or no machining of a sputtering surface in forming the desired topography can avoid waste of target blank material which occurs in prior art methodologies. Further, the flat bottom surface formed with methodology of the present invention can form a strong and uniform bond to a backing plate. Additionally, the flat bottom surface can be reproducibly utilized with conventional backing plates, without modification of the backing plates.

1-23. (canceled)

24. A PVD target consisting essentially of W and having an outer surface with a topography that is substantially an inverse of an expected wear profile of the target.

25. The PVD target of claim 24 bonded to a backing plate.

26. A PVD target consisting essentially of W and Ti; the target having an outer surface with a topography that is substantially an inverse of an expected wear profile of the target.

27. The PVD target of claim 26 bonded to a backing plate.
